(19) United States
(12) Patent Application Publication
(10) Pub. No.: US 2016/0172182 A1
(43) Pub. Date: Jun. 16, 2016

(54) LASER PROCESSING APPARATUS

(71) Applicant: DISCO CORPORATION, Tokyo (JP)

(72) Inventors: Hiroshi Morikazu, Tokyo (JP); Naoki Murazawa, Tokyo (JP); Noboru Takeda, Tokyo (JP)

(21) Appl. No.: 14/957,854

(22) Filed: Dec. 3, 2015

(30) Foreign Application Priority Data
Dec. 12, 2014 (JP) 2014-251985

(51) Int. Cl. H01L 21/02

(52) U.S. Cl. CPC H01L 21/02

(57) ABSTRACT

A laser beam irradiation unit of a laser processing apparatus includes a laser oscillator which oscillates a laser beam, an output power adjustment unit which adjusts output power of the laser beam, a condenser which converges the laser beam and irradiates the converged laser beam upon a workpiece held on a chuck table, and a rocking unit which is disposed between the laser oscillator and the condenser and rocks the laser beam oscillated by the laser oscillator in an X-axis direction and a Y-axis direction. A controller has a memory in which a processing controlling program for carrying out processing for the workpiece held on the chuck table and a marking controlling program for carrying out marking for the workpiece are stored. The processing controlling program and the marking controlling program are selected by a program selection signal from an inputting unit.

### BACKGROUND OF THE INVENTION

1. Field of the Invention

The present invention relates to a laser processing apparatus for carrying out laser processing for a workpiece such as a semiconductor wafer.

2. Description of the Related Art

In a semiconductor device fabrication process, a plurality of regions are partitioned by scheduled division lines arrayed in a grating on a front face of a semiconductor wafer having a substantially circular disk shape, and a device such as an IC or an LSI is formed in each of the partitioned regions. Then, by cutting the semiconductor wafer along the scheduled division lines, the regions in each of which a device is formed are separated from each other to fabricate individual semiconductor chips. Also an optical device wafer in which light receiving elements such as photodiodes, light emitting elements such as laser diodes and so forth are stacked on a front face of a sapphire substrate is cut along scheduled division lines and thereby divided into optical devices such as individual photodiodes and laser diodes. Such optical devices are utilized widely in electric equipment.

As a method of dividing a wafer such as a semiconductor wafer or an optical device wafer described above along scheduled division lines, a method has been put into practical use wherein a pulse laser beam is irradiated along a scheduled division line formed on a wafer to carry out ablation processing to form a laser processed groove and the wafer is divided along the scheduled division line (refer to, for example, Japanese Patent Laid-Open No. 1998-305420).

Further, as a method of dividing a wafer such as a semiconductor wafer or an optical device wafer described above along scheduled division lines, also a method has been put into practical use wherein a pulse laser beam of a wavelength having a transparency to a wafer is used and irradiated with its focused spot positioned in the inside of a region to be divided to continuously form a modified layer along a scheduled division line in the inside of the wafer, and external force is applied along the scheduled division line along which the strength of the wafer is dropped by the formation of the modified layer to divide the wafer (refer to, for example, Japanese Patent No. 348805). Meanwhile, a technology has been put into practical use wherein an ID of a device or a marking for forgery prevention is applied to the device by laser processing.

### SUMMARY OF THE INVENTION

However, in order to apply a marking to a device, a laser processing apparatus for exclusive use for marking is required, which gives rise to a problem that an equipment cost therefor is required.

Therefore, it is an object of the present invention to provide a laser processing apparatus which can carry out laser processing along a predetermined processing line for a workpiece and can apply a marking.

In accordance with an aspect of the present invention, there is provided a laser processing apparatus including a chuck table having a holding face defined by an X axis and a Y axis for holding a workpiece thereon, laser beam irradiation means for irradiating a laser beam upon the workpiece held on the chuck table, X-axis moving means for moving the chuck table and the laser beam irradiation means relative to each other in the X-axis direction, Y-axis moving means for moving the chuck table and the laser beam irradiation means relative to each other in the Y-axis direction, and control means for controlling the laser beam irradiation means, the X-axis moving means and the Y-axis moving means. The laser beam irradiation means includes laser beam oscillation means for oscillating a laser beam, output power adjustment means for adjusting output power of the laser beam oscillated by the laser beam oscillation means, a condenser configured to converge the laser beam oscillated by the laser beam oscillation means and irradiate the converged laser beam upon the workpiece held on the chuck table, and rocking means disposed between the laser beam oscillation means and the condenser for rocking the laser beam oscillated by the laser beam oscillation means in the X-axis direction and the Y-axis direction. The control means includes a memory in which a processing controlling program for carrying out processing for the workpiece held on the chuck table and a marking controlling program for applying a marking to the workpiece are stored. The processing controlling program and the marking controlling program are selected by a program selection signal from inputting means.

Preferably, the laser beam irradiation means includes a wavelength conversion mechanism configured to convert a wavelength of the laser beam oscillated by the laser beam oscillation means.

With the laser processing apparatus of the present invention, the control means of the laser processing apparatus includes the memory in which the processing controlling program for carrying out processing for a workpiece held on the chuck table and the marking controlling program for carrying out marking for the workpiece are stored. The processing controlling program and the making controlling program are selected by the program selection signal from the inputting unit. Therefore, if the processing controlling program is selected, then processing can be carried out along a processing line of the workpiece. On the other hand, if the marking controlling program is selected, then an ID or a mark for forgery prevention can be formed. Consequently, the equipment cost can be reduced.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1 is a perspective view of a laser processing apparatus;

FIG. 2 is a block diagram of laser beam irradiation means provided in the laser processing apparatus depicted in FIG. 1;

FIG. 3 is a perspective view of wavelength conversion means which configures a wavelength conversion mechanism provided in the laser beam irradiation means depicted in FIG. 2;

FIG. 4 is a block diagram of control means provided in the laser processing apparatus depicted in FIG. 1;

FIG. 5 is a perspective view of a semiconductor wafer as a workpiece;

FIG. 6 is a perspective view depicting the semiconductor wafer depicted in FIG. 5 but in a state in which the semiconductor wafer is pasted to an adhesive tape mounted on an annular frame;

FIGS. 7A and 7B are schematic views of a modified layer forming step carried out by the laser processing apparatus depicted in FIG. 1; and

FIG. 8 is a schematic view of a marking step carried out by the laser processing apparatus depicted in FIG. 1.

### DETAILED DESCRIPTION OF THE PREFERRED EMBODIMENT

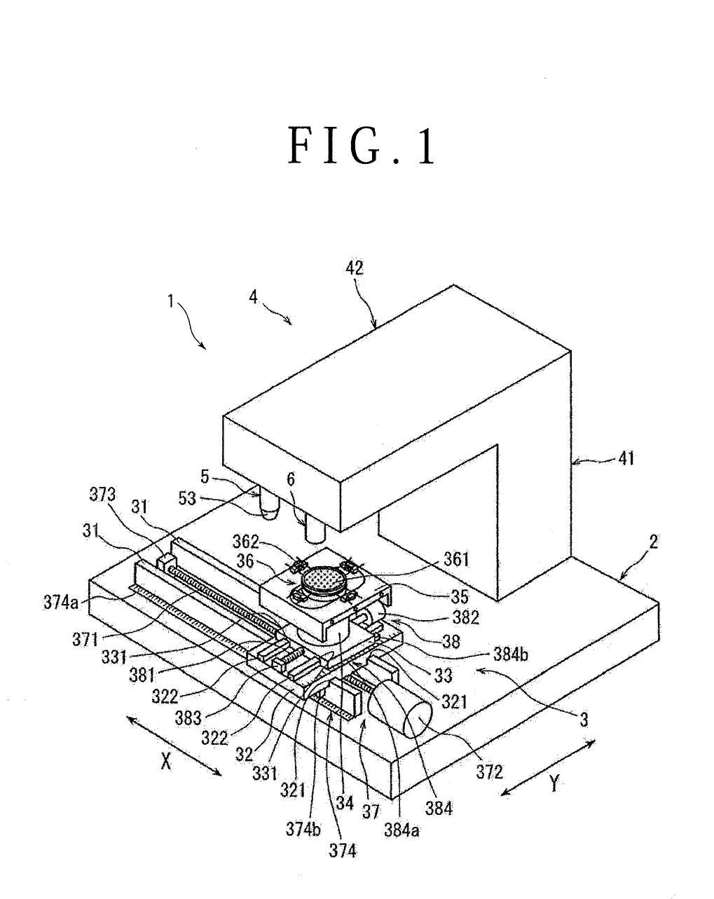

In the following, a preferred embodiment of a laser processing apparatus configured in accordance with the present invention is described in detail with reference to the accompanying drawings. FIG. 1 depicts a perspective view of a laser processing apparatus 1 configured in accordance with the present invention. The laser processing apparatus 1 depicted in FIG. 1 includes a stationary base 2, a chuck table mechanism 3 disposed for movement in an X-axis direction, which is a processing feeding direction, indicated by an arrow mark X on the stationary base 2 and configured to hold a workpiece thereon, and a laser beam irradiation unit 4 as laser beam irradiation means disposed on the stationary base 2.

The chuck table mechanism 3 includes a pair of guide rails 31 disposed in parallel along the X-axis direction on the stationary base 2, a first sliding block 32 disposed for movement in the X-axis direction on the guide rails 31, a second sliding block 33 disposed for movement in a Y-axis direction, which is an indexing direction, indicated by an arrow mark Y orthogonal to the X-axis direction on the first sliding block 32, a support table 35 supported by a cylindrical member 34 on the second sliding block 33, and a chuck table 36 as workpiece holding means. The chuck table 36 includes an absorption chuck 361 configured from a porous material, and, for example, a circular semiconductor wafer which is a workpiece is held by suction means not depicted on a holding face which is an upper face of the absorption chuck 361 and is defined by an X axis and a Y axis. The chuck table 36 configured in such a manner as just described is rotated by a stepping motor not depicted disposed in the cylindrical member 34. It is to be noted that a clamp 362 for fixing an annular frame for supporting a workpiece such as a semiconductor wafer through a protective tape is disposed on the chuck table 36.

The first sliding block 32 includes a pair of guiding target grooves 321 provided on the lower face thereof for fitting with the pair of guide rails 31 and a pair of guide rails 322 formed in parallel along the Y-axis direction and provided on the upper face thereof. The first sliding block 32 configured in such a manner as just described is configured for movement in the X-axis direction along the pair of guide rails 31 by fitting the guiding target grooves 321 with the pair of guide rails 31. The chuck table mechanism 3 in the present embodiment includes X-axis direction moving means 37 for moving the first sliding block 32 in the X-axis direction along the pair of guide rails 31. The X-axis direction moving means 37 includes an external thread rod 371 disposed in parallel to and between the pair of guide rails 31 and a driving source such as a stepping motor 372 for driving the external thread rod 371 to rotate. The external thread rod 371 is supported at one end thereof for rotation on a bearing block 373 fixed to the stationary base 2 and transmission-coupled at the other end thereof to an output power shaft of the stepping motor 372. It is to be noted that the external thread rod 371 is screwed into a penetrating internal thread hole formed on an internal thread block not depicted provided in a projecting manner on the lower face of a central portion of the first sliding block 32. Accordingly, by driving the external thread rod 371 for forward rotation and reverse rotation by the stepping motor 372, the first sliding block 32 is moved in the X-axis direction along the guide rails 31.

The laser processing apparatus 1 includes X-axis direction position detection means 374 for detecting an X-axis direction position of the chuck table 36. The X-axis direction position detection means 374 is configured from a linear scale 374a disposed along the guide rails 31, and a reading head 374b disposed on the first sliding block 32 and movable along the linear scale 374a together with the first sliding block 32. The reading head 374b of the X-axis direction position detection means 374 sends a pulse signal, in the present embodiment, of one pulse after every 1 μm to control means hereinafter described. Then, the control means hereinafter described counts the pulse signal inputted thereto to detect the X-axis direction position of the chuck table 36. It is to be noted that, where the stepping motor 372 is used as a driving source for the X-axis direction moving means 37, also it is possible to detect the X-axis direction position of the chuck table 36 by counting driving pulses of the control means hereinafter described which outputs a driving signal to the stepping motor 372. On the other hand, where a servomotor is used as the driving source for the X-axis direction moving means 37, also it is possible to send a pulse signal outputted from a rotary encoder for detecting the number of rotations of the servomotor to the control means hereinafter described so that the control means counts the inputted pulse signal to detect the X-axis direction position of the chuck table 36.

The second sliding block 33 includes a pair of guiding target grooves 331 provided on the lower face thereof for fitting with the pair of guide rails 322 provided on the upper face of the first sliding block 32, and is configured for movement in the Y-axis direction by fitting the guiding target grooves 331 with the pair of guide rails 322. The chuck table mechanism 3 includes Y-axis direction moving means 38 for moving the second sliding block 33 in the Y-axis direction along the pair of guide rails 322 provided on the first sliding block 32. The Y-axis direction moving means 38 includes an external thread rod 381 disposed in parallel to and between the pair of guide rails 322 and a driving source such as a stepping motor 382 for driving the external thread rod 381 to rotate. The external thread rod 381 is supported at one end thereof for rotation on a bearing block 383 fixed to the upper face of the first sliding block 32 and transmission-coupled at the other end thereof to an output power shaft of the stepping motor 382. It is to be noted that the external thread rod 381 is screwed in a penetrating internal thread hole formed on an internal thread block not depicted provided in a projecting manner on the lower face of a central portion of the second sliding block 33. Accordingly, by driving the external thread rod 381 for forward rotation and reverse rotation by the stepping motor 382, the second sliding block 33 is moved in the Y-axis direction along the guide rails 322.

The laser processing apparatus 1 includes Y-axis direction position detection means 384 for detecting the Y-axis direction position of the second sliding block 33. The Y-axis direction position detection means 384 is configured from a linear scale 384a disposed along the guide rails 322, and a reading head 384b disposed on the second sliding block 33 and movable along the linear scale 384a together with the second sliding block 33. The reading head 384b of the Y-axis direction position detection means 384 sends a pulse signal, in the present embodiment, of one pulse after every 1 μm to the control means hereinafter described. Thus, the control means hereinafter described detects the Y-axis direction position of the chuck table 36 by counting the pulse signal inputted thereto. It is to be noted that, where the stepping motor 382 is used as the driving force for the Y-axis direction moving means 38, it is possible to detect the Y-axis direction position of the chuck table 36 by counting the driving pulse of the control means hereinafter described which outputs a driving signal to the stepping motor 382. On the other hand, where a servomotor is used as the driving source for the Y-axis direction moving means 38, also it is possible to send a pulse signal outputted from a rotary encoder for detecting the number of rotations of the servomotor to the control means hereinafter described such that the control means can detect the Y-axis direction position of the chuck table 36 by counting the pulse signal inputted thereto.

The laser beam irradiation unit 4 includes a support member 41 disposed on the stationary base 2, a casing 42 supported by the support member 41 and extending substantially in a horizontal direction, laser beam irradiation means 5 disposed on the casing 42, and image pickup means 6 disposed at a front end portion of the casing 42 for detecting a processing region for which laser processing is to be carried out. It is to be noted that the image pickup means 6 in the present embodiment includes, in addition to an ordinary image pickup device (CCD) for picking up an image using visible rays, infrared illumination means for irradiating infrared rays on a workpiece, an optical system for capturing the infrared rays irradiated from the infrared illumination means, an image pickup device (infrared CCD) for outputting an electric signal corresponding to the infrared rays captured by the optical system, and so forth. An image signal obtained by the image pickup is sent to the control means hereinafter described.

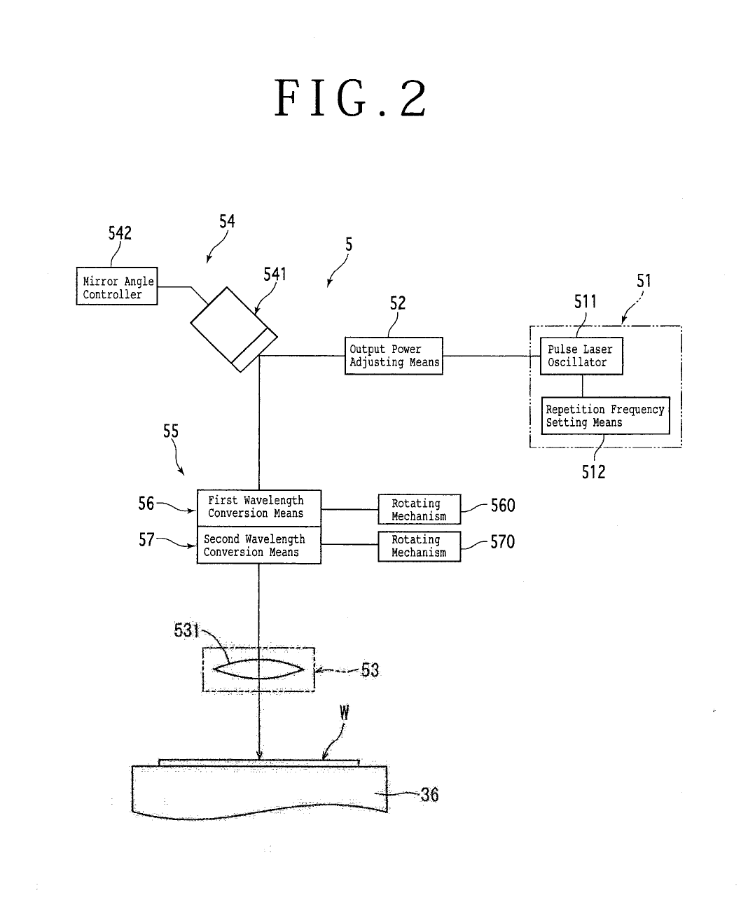

The laser beam irradiation means 5 is described with reference to FIG. 2. The laser beam irradiation means 5 includes pulse laser beam oscillation means 51, output power adjustment means 52, a condenser 53, rocking means 54 and a wavelength conversion mechanism 55. The pulse laser beam oscillation means 51 is disposed in the casing 42. The output power adjustment means 52 adjusts the output power of a pulse laser beam oscillated by the pulse laser beam oscillation means 51. The condenser 53 converges the pulse laser beam oscillated by the pulse laser beam oscillation means 51 and irradiates the converged pulse laser beam upon a workpiece W held on the chuck table 36. The rocking means 54 is disposed between the pulse laser beam oscillation means 51 and the condenser 53 and rocks the pulse laser beam oscillated by the pulse laser beam oscillation means 51 in the X-axis direction and the Y-axis direction. The wavelength conversion mechanism 55 converts the wavelength of the pulse laser beam oscillated by the pulse laser beam oscillation means 51.

The pulse laser beam oscillation means 51 is configured from a pulse laser beam oscillator 511 which oscillates a pulse laser beam having, in the present embodiment, a wavelength of 1064 nm, and repetition frequency setting means 512 for setting the repetition frequency of the pulse laser beam oscillated by the pulse laser beam oscillator 511. The output power adjustment means 52 adjusts the output power of the pulse laser beam oscillated by the pulse laser beam oscillation means 51 to predetermined output power. The condenser 53 includes a condensing lens 531 which converges the pulse laser beam oscillated by the pulse laser beam oscillation means 51 and irradiates the converged pulse laser beam upon the workpiece W held on the chuck table 36. The condenser 53 is mounted at a tip end of the casing 42 as depicted in FIG. 1.

The rocking means 54 is configured, in the present embodiment, from an angularly adjustable mirror 541, and the angle thereof is adjusted by a mirror angle controller 542. The mirror angle controller 542 can deflect the angularly adjustable mirror 541 in the X-axis direction and the Y-axis direction and is controlled by the control means hereinafter described.

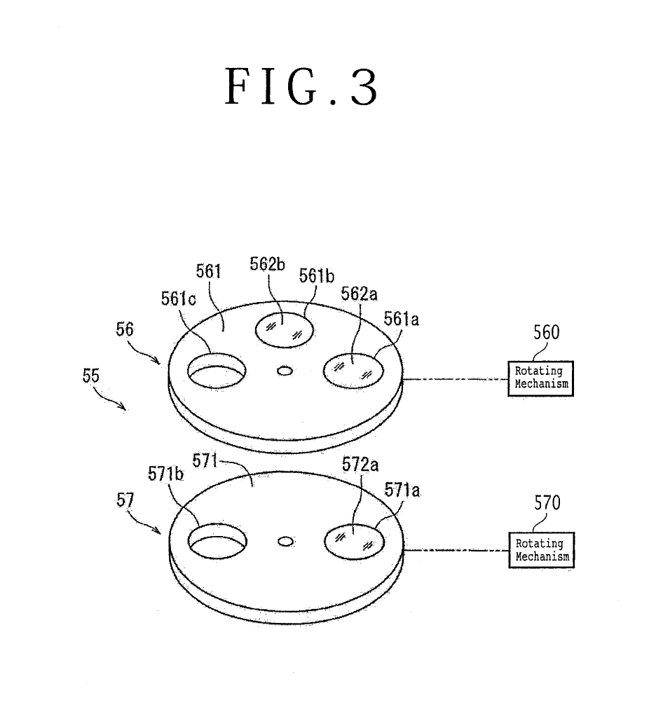

Now, the wavelength conversion mechanism 55 is described with reference to FIG. 3. The wavelength conversion mechanism 55 in the present embodiment is configured from first wavelength conversion means 56 and second wavelength conversion means 57 as depicted in FIG. 3. The first wavelength conversion means 56 includes a rotatable disk 561. The rotatable disk 561 has, in the present embodiment, three through-holes 561a, 561b and 561c. In the through-hole 561a of the rotatable disk 561 formed in this manner, wavelength conversion crystal 562a configured from LBO crystal is disposed; in the through-hole 561b, wavelength conversion crystal 562b configured from BBO crystal is disposed; and in the through-hole 561c, no wavelength conversion crystal is disposed. Also the second wavelength conversion means 57 includes a rotatable disk 571 similarly to the first wavelength conversion means 56. The rotatable disk 571 has, in the present embodiment, two through-holes 571a and 571b. In the through-hole 571a of the rotatable disk 571 formed in this manner, wavelength conversion crystal 572a formed from CLBO crystal is disposed, and in the through-hole 571b, no wavelength conversion crystal is disposed.

The first wavelength conversion means 56 and the second wavelength conversion means 57 configured in such a manner as described above are disposed in an opposing relationship to each other in an axial direction thereof and are rotated around the axis thereof by rotating mechanisms 560 and 570, respectively. The rotating mechanisms 560 and 570 for driving the rotatable disk 561 and the rotatable disk 571 to rotate are controlled by the control means hereinafter described. It is to be noted that the wavelength conversion crystal 562a formed from LBO crystal, the wavelength conversion crystal 562b formed from BBO crystal and the wavelength conversion crystal 572a formed from CLBO crystal individually have a function for converting the wavelength of the laser beam inputted thereto into a wavelength of one half. Accordingly, the pulse laser beam of a wavelength of 1064 nm oscillated by the pulse laser beam oscillation means 51 is converted into a pulse laser beam of another wavelength of 532 nm when it passes only through the wavelength conversion crystal 562a formed from LBO crystal. Meanwhile, the pulse laser beam of a wavelength of 1064 nm oscillated by the pulse laser beam oscillation means 51 is converted into a pulse laser beam of a further wavelength of 266 nm when it passes through the wavelength conversion crystal 562b formed from BBO crystal and the wavelength conversion crystal 572a formed from CLBO crystal. It is to be noted that, if the through-hole 561c of the rotatable disk 561 and the through-hole 571b of the rotatable disk 571 are registered with each other, then the pulse laser beam of a wavelength of 1064 nm oscillated by the pulse laser beam oscillation means 51 is outputted as it is.

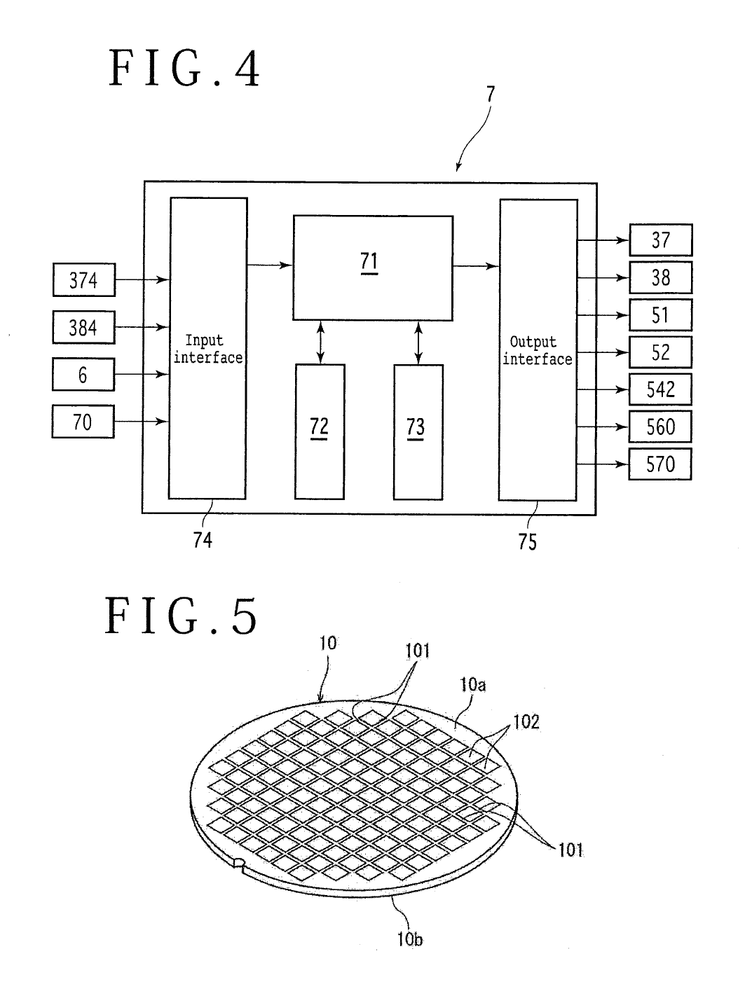

The laser processing apparatus 1 includes control means 7 depicted in FIG. 4. The control means 7 is configured from a computer and includes a central processing unit (CPU) 71 which carries out arithmetic operation processing in accordance with a control program, a program memory 72 for storing the control program, a readable and writable random access memory 73 for storing a result of arithmetic operation processing and so forth, an input interface 74, and an output interface 75. To the input interface 74 of the control means 7, detection signals from the X-axis direction position detection means 374, the Y-axis direction position detection means 384, the image pickup means 6, inputting means 70 and so forth are inputted. Meanwhile, from the output interface 75 of the control means 7, control signals are outputted to the X-axis direction moving means 37, the Y-axis direction moving means 38, the pulse laser beam oscillation means 51 and the output adjustment means 52 of the laser beam irradiation means 5, the mirror angle controller 542 of the rocking means 54, the rotating mechanism 560 for rotating the rotatable disk 561 which configures the first wavelength conversion means 56 of the wavelength conversion mechanism 55, the rotating mechanism 570 for rotating the rotatable disk 571 which configures the second wavelength conversion means 57 of the wavelength conversion mechanism 55 and so forth. It is to be noted that, in the program memory 72, a processing controlling program for carrying out processing for a workpiece and a marking controlling program for carrying out marking for a workpiece are stored. The processing controlling program and the marking controlling program stored in the program memory 72 are selected by the inputting means 70. Further, the random access memory 73 has characters or graphics for marking stored therein.

The laser processing apparatus 1 is configured in such a manner as described above, and in the following, operation of the laser processing apparatus 1 is described. FIG. 5 depicts a perspective view of a semiconductor wafer 10 as a workpiece to be processed by the laser processing apparatus 1 described hereinabove. The semiconductor wafer 10 depicted in FIG. 5 is a silicon wafer, and has a plurality of scheduled division lines 101 formed in a grating on a front face 10a thereof and has devices 102 such as ICs or LSIs in a plurality of regions partitioned by the scheduled division lines 101.

Processing for forming a modified layer along a scheduled division line 101 in the inside of the semiconductor wafer 10 described above is described. In order to carry out a modified layer forming step of forming a modified layer, the processing controlling program is selected as the control program of the program memory 72 by the inputting means 70 described above. Then, the through-hole 561c of the rotatable disk 561 configuring the first wavelength conversion means 56 of the wavelength conversion mechanism 55 and the through-hole 571b of the rotatable disk 571 configuring the second wavelength conversion means 57 are registered with each other so that the pulse laser beam of a wavelength of 1064 nm oscillated by the pulse laser beam oscillation means 51 may be outputted as it is. Further, the angularly adjustable mirror 541 as the rocking means 54 is fixed to an angular position by which the direction of the pulse laser beam oscillated by pulse laser beam oscillation means 51 is converted so as to be perpendicular to the holding face of the chuck table 36.

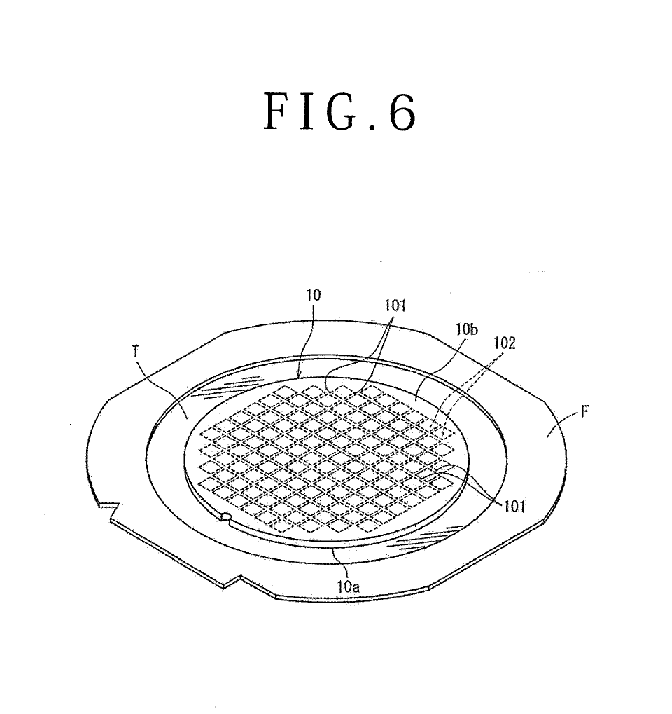

Then, in order to form a modified layer along a scheduled division line 101 in the inside of the semiconductor wafer 10 described above, a workpiece supporting step is carried out first for pasting an adhesive tape made of a synthetic resin at a front face thereof to the front face 10a of the semiconductor wafer 10 and supporting the adhesive tape at an outer peripheral portion thereof by an annular frame. In particular, as depicted in FIG. 6, the semiconductor wafer 10 is pasted at the front face 10a thereof to a front face of an adhesive tape T which is mounted at an outer peripheral portion thereof so as to cover an inner side opening of an annular frame F. It is to be noted that the adhesive tape T is formed, in the present embodiment depicted, from a polyvinyl chloride (PVC) sheet.

After the workpiece supporting step described above is carried out, the semiconductor wafer 10 is placed at the adhesive tape T side thereof on the chuck table 36 of the laser processing apparatus 1 depicted in FIG. 1. Then, the suction means not depicted is rendered operative to suck and hold the semiconductor wafer 10 to and on the chuck table 36 with the adhesive tape T interposed therebetween (workpiece holding step). Accordingly, the semiconductor wafer 10 held on the chuck table 36 with the adhesive tape T interposed therebetween is postured such that a rear face 10b thereof is positioned on the upper side. It is to be noted that the annular frame F on which the semiconductor wafer 10 is supported with the adhesive tape T interposed therebetween is fixed by the clamp 362 disposed on the chuck table 36.

After the workpiece holding step is carried out, the X-axis direction moving means 37 is rendered operative to position the chuck table 36, to and on which the semiconductor wafer 10 is sucked and held, just below the image pickup means 6. After the chuck table 36 is positioned just below the image pickup means 6, an alignment process for detecting a processing region of the semiconductor wafer 10 to be laser-processed is executed by the image pickup means 6 and the control means 7. In particular, the image pickup means 6 and the control means 7 execute an image process such as pattern matching for carrying out positioning of a scheduled division line 101 formed in a first direction of the semiconductor wafer 10 with respect to the condenser 53 of the laser beam irradiation means 5 for irradiating a laser beam to establish alignment of the laser beam irradiation position. Further, alignment of the laser beam irradiation position is carried out similarly also with respect to a scheduled division line 101 formed in a direction orthogonal to the first direction on the semiconductor wafer 10. At this time, although the front face 10a of the semiconductor wafer 10 on which the scheduled division lines 101 are formed is positioned on the lower side, since the image pickup means 6 configured from infrared illumination means, an optical system for capturing infrared rays, an image pickup device (infrared CCD) which outputs an electric signal corresponding to infrared rays and so forth is provided, an image of the scheduled division line 101 can be picked up penetratingly from the rear face 10b side.

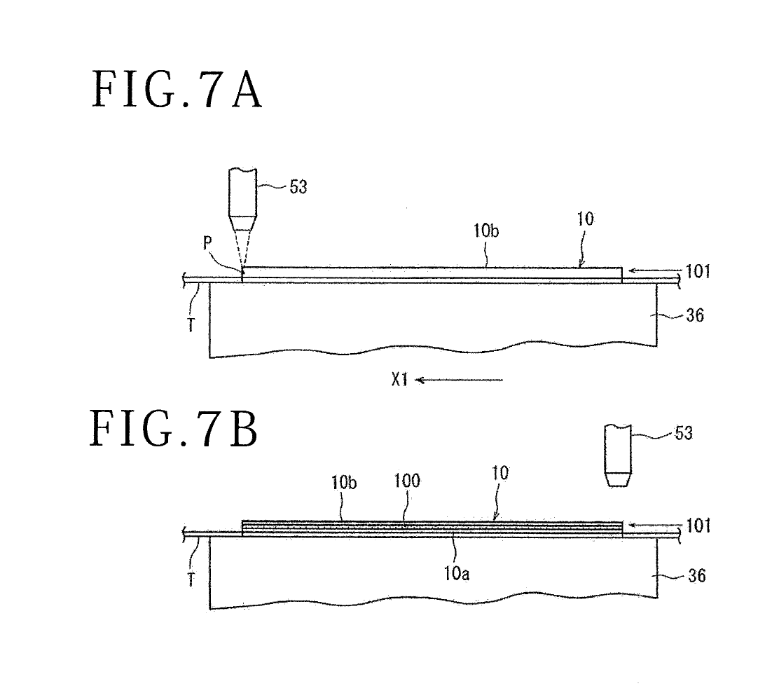

After the scheduled division lines 101 formed on the semiconductor wafer 10 held on the chuck table 36 are detected and alignment of the laser beam irradiation position is carried out in such a manner as described above, the chuck table 36 is moved to the laser beam irradiation region in which the condenser 53 of the laser beam irradiation means 5 which irradiates the laser beam is positioned to position one end (left end in FIG. 7A) of a predetermined scheduled division line 101 just below the condenser 53 of the laser beam irradiation means 5 as depicted in FIG. 7A. Then, the focused point P of the pulse laser beam irradiated from the condenser 53 is positioned at an intermediate portion in the thicknesswise direction of the semiconductor wafer 10. Then, the laser beam irradiation means 5 is rendered operative to irradiate a pulse laser beam from the condenser 53 while the chuck table 36 is moved at a predetermined feeding speed in a direction indicated by an arrow mark X1 in FIG. 7A. At this time, since the through-hole 561c of the rotatable disk 561 configuring the first wavelength conversion means 56 of the wavelength conversion mechanism 55 and the through-hole 571b of the rotatable disk 571 configuring the second wavelength conversion means 57 are registered with each other so that a pulse laser beam of a wavelength of 1064 nm oscillated by the pulse laser beam oscillation means 51 may be outputted as it is, a pulse laser beam of a wavelength (1064 nm) having a transparency to the silicon wafer is irradiated from the condenser 53. Then, if the irradiation position of the condenser 53 of the laser beam irradiation means 5 comes to the position of the other end of the scheduled division line 101 as depicted in FIG. 7B, then the irradiation of the pulse laser beam is stopped and the movement of the chuck table 36 is stopped. As a result, in the inside of the semiconductor wafer 10, a modified layer 100 is formed along the scheduled division line 101.

The modified layer forming step is carried out, for example, in accordance with the following processing conditions.

Light source: YAG pulse laser

Wavelength: 1064 nm

Repetition frequency: 50 kHz

Average output power: 0.5 W

Focused spot diameter: 1 μm

Processing feeding speed: 100 mm/second

After the modified layer forming step is executed along the predetermined scheduled division line 101 as described above, the chuck table 36 is indexing-fed by a distance between the scheduled division lines 101 formed on the semiconductor wafer 10 in the direction indicated by the arrow mark Y (indexing feeding step) to carry out the modified layer forming step. After the modified layer forming step is carried out along all of the scheduled division lines 101 formed in the first direction in this manner, the chuck table 36 is rotated by 90 degrees, whereafter the modified layer forming step described above is executed along the scheduled division lines 101 extending in the direction perpendicular to the scheduled division lines 101 formed in the first direction.

Thereafter, a marking step for applying a marking of device information to a region corresponding to a device on the rear face 10b of the semiconductor wafer 10 is carried out in a state after the modified layer forming step is carried out. A marking step for applying a predetermined marking to a region corresponding to a device is described. In order to carry out the marking step, the marking controlling program is selected as the control program of the program memory 72 by the inputting means 70. Then, the wavelength conversion crystal 562a formed from LBO crystal of the rotatable disk 561 configuring the first wavelength conversion means 56 of the wavelength conversion mechanism 55 and the through-hole 571b of the rotatable disk 571 configuring the second wavelength conversion means 57 are registered with each other so that the pulse laser beam of a wavelength of 1064 nm oscillated by the pulse laser beam oscillation means 51 may be converted into a pulse laser beam of a different wavelength of 532 nm having an absorbency to the silicon wafer. Further, the angularly adjustable mirror 541 as the rocking means 54 is positioned to an angular position by which the pulse laser beam oscillated by the pulse laser beam oscillation means 51 advances perpendicularly to the holding face of the chuck table 36.

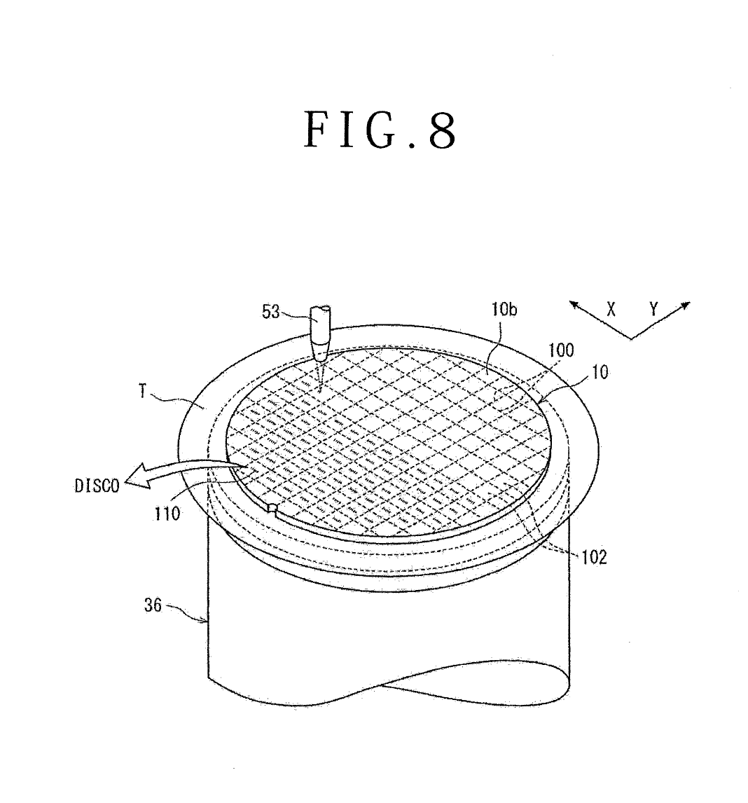

Then, the condenser 53 of the laser beam irradiation means 5 is positioned to a region of the rear face 10b of the semiconductor wafer 10 corresponding to the device 102 formed in a region partitioned by the scheduled division lines 101 as depicted in FIG. 8. Then, while the pulse laser beam (pulse laser beam of a wavelength of 532 nm having an absorbency to the silicon wafer) is irradiated from the condenser 53, the control means 7 outputs a control signal to the mirror angle controller 542 on the basis of a character or a graphic to be marked stored in the random access memory 73. As a result, the angularly adjustable mirror 541 as the rocking means 54 is deflected in the X-axis direction or the Y-axis direction in accordance with the character or graphic to be marked. Consequently, an ID or a mark 110 for forgery prevention is formed in the region corresponding to the device 102 on the rear face 10b of the semiconductor wafer 10.

It is to be noted that the processing conditions at the marking step are set, for example, in the following manner.

Light source: YAG pulse laser

Wavelength: 1064 nm→532 nm

Repetition frequency: 50 kHz

Average output power: 5 W

Focused spot diameter (defocusing): 10 μm

In the foregoing description of the embodiment, the example is described in which the marking step is carried out by registering the wavelength conversion crystal 562a formed from LBO crystal of the rotatable disk 561 configuring the first wavelength conversion means 56 of the wavelength conversion mechanism 55 and the through-hole 571b of the rotatable disk 571 configuring the second wavelength conversion means 57 with each other to adjust the pulse laser beam of a wavelength of 1064 nm oscillated by the pulse laser beam oscillation means 51 to a pulse laser beam of another wavelength of 532 nm. However, depending upon the material of the workpiece, the marking step may be carried out by registering the wavelength conversion crystal 562b formed from BBO crystal of the rotatable disk 561 configuring the first wavelength conversion means 56 and the wavelength conversion crystal 572a formed from CLBO crystal of the rotatable disk 571 configuring the second wavelength conversion means 57 with each other to adjust the pulse laser beam of a wavelength of 1064 nm oscillated by the pulse laser beam oscillation means 51 to a pulse laser beam of a different wavelength of 266 nm.

Further, if a pulse laser beam of a wavelength of 532 nm or 266 nm to which the pulse laser beam of a wavelength of 1064 nm oscillated by the pulse laser beam oscillation means 51 is adjusted is irradiated along a scheduled division line 101 of the semiconductor wafer 10 to carry out ablation processing along the scheduled division line 101 on the front face 10a of the semiconductor wafer 10, then a laser processed groove can be formed along the scheduled division line 101 of the semiconductor wafer 10.

As described above, with the laser processing apparatus 1 of the present embodiment, if the processing controlling program or the marking controlling process is selected as the control program of the program memory 72 and the pulse laser beam of a wavelength of 1064 nm oscillated by the pulse laser beam oscillation means 51 is adjusted to a laser beam of a desired wavelength (1064 nm, 532 nm or 266 nm) using the first wavelength conversion means 56, then processing can be carried out along a scheduled division line 101 of the semiconductor wafer 10 and an ID or a mark 110 for forgery prevention can be formed. Consequently, the equipment cost can be reduced.

While the present invention has been described in connection with the embodiment depicted in the drawings, the present invention is not limited only to the embodiment described above but can be modified in various forms without departing from the scope and spirit of the present invention. For example, in the embodiment described above, the angularly adjustable mirror 541 and the mirror angle controller 542 are used as the rocking means 54 for rocking the pulse laser beam oscillated by the pulse laser beam oscillation means 51 in the X-axis direction and the Y-axis direction. However, as the rocking means, a galvano scanner for the X-axis direction and another galvano scanner for the Y-axis direction or an acousto-optical element for the X-axis direction and an acousto-optical element for the Y-axis direction may be used instead. Further, in the foregoing description of the embodiment, an example is described in which the wavelength conversion mechanism 55 is configured from the first wavelength conversion means 56 including the wavelength conversion crystal 562a formed from LBO crystal and the wavelength conversion crystal 562b formed from BBO crystal and the second wavelength conversion means 57 including the wavelength conversion crystal 572a formed from CLBO crystal. However, for example, a wavelength conversion plate which converts a pulse laser beam of a wavelength of 1064 nm into a pulse laser beam of a predetermined wavelength set in advance and outputs the pulse laser beam of the predetermined wavelength with a predetermined angle may be used instead. Further, in the foregoing description of the embodiment, pulse laser beams of wavelengths of 1064 nm, 532 nm and 266 nm are irradiated upon a workpiece through the single condenser 53. However, the optical path of the pulse laser beam of a wavelength of 1064 nm and the optical path of the laser beams of wavelengths of 532 nm and 266 nm may be separated from each other, and a condenser for converging and irradiating a pulse laser beam may be provided on each of the optical paths.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A laser processing apparatus, comprising:
a chuck table having a holding face defined by an X axis and a Y axis for holding a workpiece thereon;
laser beam irradiation means for irradiating a laser beam upon the workpiece held on the chuck table;
X-axis moving means for moving the chuck table and the laser beam irradiation means relative to each other in the X-axis direction;
Y-axis moving means for moving the chuck table and the laser beam irradiation means relative to each other in the Y-axis direction; and
control means for controlling the laser beam irradiation means, the X-axis moving means and the Y-axis moving means;
the laser beam irradiation means including
laser beam oscillation means for oscillating a laser beam,
output power adjustment means for adjusting output power of the laser beam oscillated by the laser beam oscillation means,
a condenser configured to converge the laser beam oscillated by the laser beam oscillation means and irradiate the converged laser beam upon the workpiece held on the chuck table, and
rocking means disposed between the laser beam oscillation means and the condenser for rocking the laser beam oscillated by the laser beam oscillation means in the X-axis direction and the Y-axis direction;
the control means including a memory in which a processing controlling program for carrying out processing for the workpiece held on the chuck table and a marking controlling program for applying a marking to the workpiece are stored;
the processing controlling program and the marking controlling program being selected by a program selection signal from inputting means.

2. The laser processing apparatus according to claim 1, wherein the laser beam irradiation means includes a wavelength conversion mechanism configured to convert a wavelength of the laser beam oscillated by the laser beam oscillation means.
